(19) United States
(12) Patent Application Publication
(10) Pub. No.: US 2022/0154536 A1
(43) Pub. Date: May 19, 2022

(54) THERMAL ANALYSIS OF DRILL BITS

(71) Applicant: National Oilwell Varco, L.P., Houston, TX (US)

(72) Inventors: Afshin Babaie Aghdam, Houston, TX (US); Navid Omidvar, Houston, TX (US); Brad Ivie, Houston, TX (US)

(73) Assignee: National Oilwell Varco, L.P., Houston, TX (US)

(21) Appl. No.: 17/440,289

(22) PCT Filed: Mar. 18, 2020
(86) PCT No.: PCT/US2020/023279

§ 371 Date: Sep. 17, 2021

Related U.S. Application Data
(60) Provisional application No. 62/819,756, filed on Mar. 18, 2019.

(51) Int. Cl. E21B 10/46; E21B 47/07; G06F 30/23

(52) U.S. Cl. CPC E21B 10/46; E21B 2200/20; G06F 30/23; E21B 47/07

(57) ABSTRACT

A method includes receiving a drill bit design, which specifies design parameters related to a plurality of cutter elements of the drill bit. The method also includes estimating a thermal impact value for the cutter elements based on the design parameters and one or more drilling parameters, and estimating a cooling capacity value for the cutter elements based on the design and one or more cooling parameters. Finally, the method includes presenting the thermal impact values or the cooling capacity values together or individually on a per cutter element basis or as a function of a geometrical or physical property of the cutter elements.

### CROSS-REFERENCE TO RELATED APPLICATIONS

The present application claims benefit of U.S. provisional patent application No. 62/819,756 filed on Mar. 18, 2019, and entitled “Thermal Analysis of Drill Bits” which is incorporated herein by reference in its entirety.

### STATEMENT REGARDING FEDERALLY SPONSORED RESEARCH OR DEVELOPMENT

Not applicable.

### BACKGROUND

The disclosure relates generally to designing drill bits for drilling a borehole in an earthen formation for the ultimate recovery of oil, gas, or minerals. More particularly, the disclosure relates to designing drill bits to improve the thermal wear life of drill bit cutter elements.

An earth-boring drill bit is typically mounted on the lower end of a drill string and is rotated by rotating the drill string at the surface or by actuation of downhole motors or turbines, or by both methods. With weight applied to the drill string, the rotating drill bit engages the earthen formation and proceeds to form a borehole along a predetermined path toward a target zone. The borehole thus created will have a diameter generally equal to the diameter or “gage” of the drill bit.

Fixed cutter bits, also known as rotary drag bits, are one type of drill bit commonly used to drill boreholes. Fixed cutter bit designs include a plurality of blades angularly spaced about the bit face. The blades generally project radially outward along the bit body and form flow channels there between. In addition, cutter elements are often grouped and mounted on several blades. The configuration or layout of the cutter elements on the blades may vary widely, depending on a number of factors.

The cutter elements disposed on the several blades of a fixed cutter bit are typically formed of extremely hard materials and include a layer of polycrystalline diamond (“PCD”) material. In the typical fixed cutter bit, each cutter element or assembly comprises an elongate and generally cylindrical support member which is received and secured in a pocket formed in the surface of one of the several blades. In addition, each cutter element typically has a hard cutting layer of polycrystalline diamond or other superabrasive material such as cubic boron nitride, thermally stable diamond, polycrystalline cubic boron nitride, or ultrahard tungsten carbide (meaning a tungsten carbide material having a wear-resistance that is greater than the wear-resistance of the material forming the substrate) as well as mixtures or combinations of these materials. The cutting layer is exposed on one end of its support member, which is typically formed of tungsten carbide. For convenience, as used herein, reference to “PDC bit” or “PDC cutter element” refers to a fixed cutter bit or cutting element employing a hard cutting layer of polycrystalline diamond or other superabrasive material such as cubic boron nitride, thermally stable diamond, polycrystalline cubic boron nitride, or ultrahard tungsten carbide.

While the bit is rotated, drilling fluid is pumped through the drill string and directed out of the face of the drill bit. The fixed cutter bit typically includes nozzles or fixed ports spaced about the bit face that serve to inject drilling fluid into the flow passageways between the several blades. The flowing fluid performs several important functions. The fluid removes formation cuttings from the bit's cutting structure. Otherwise, accumulation of formation materials on the cutting structure may reduce or prevent the penetration of the cutting structure into the formation. In addition, the fluid removes cut formation materials from the bottom of the hole. Failure to remove formation materials from the bottom of the hole may result in subsequent passes by cutting structure to re-cut the same materials, thereby reducing the effective cutting rate and potentially increasing wear on the cutting surfaces. The drilling fluid and cuttings removed from the bit face and from the bottom of the hole are forced from the bottom of the borehole to the surface through the annulus that exists between the drill string and the borehole sidewall. Further, the fluid removes heat, caused by contact with the formation, from the cutter elements in order to prolong cutter element life. Thus, the number and placement of drilling fluid nozzles, and the resulting flow of drilling fluid, may significantly impact the performance of the drill bit, in particular the thermal wear life of the PDC cutter elements.

Without regard to the type of bit, the cost of drilling a borehole for recovery of hydrocarbons may be very high, and is proportional to the length of time it takes to drill to the desired depth and location. The time required to drill the well, in turn, is greatly affected by the number of times the drill bit must be changed before reaching the targeted formation. This is the case because each time the bit is changed, the entire string of drill pipe, which may be miles long, must be retrieved from the borehole, section by section. Once the drill string has been retrieved and the new bit installed, the bit must be lowered to the bottom of the borehole on the drill string, which again must be constructed section by section. As is thus obvious, this process, known as a “trip” of the drill string, requires considerable time, effort, and expense. Accordingly, it is desirable to employ drill bits which will drill faster and longer. The length of time that a drill bit may be employed before it must be changed depends upon a variety of factors, including thermal wear life of the PDC cutter elements.

### BRIEF SUMMARY OF THE DISCLOSURE

Examples of the present disclosure are directed to a method that includes receiving a drill bit design that specifies design parameters related to a plurality of cutter elements of the drill bit, estimating a thermal impact value for the cutter elements based on the design parameters and one or more drilling parameters, and estimating a cooling capacity value for the cutter elements based on the design and one or more cooling parameters. The method also includes presenting one or more of the thermal impact values and the cooling capacity values responsive to a user input selecting one of a presentation on a per cutter element basis or as a function of a property of the cutter elements.

Other examples of the present disclosure are directed to a non-transitory, computer-readable medium containing instructions that, when executed by a processor, cause the processor to receive a drill bit design from a memory, the design specifying design parameters related to a plurality of cutter elements of the drill bit; estimate a thermal impact value for the cutter elements based on the design parameters and one or more drilling parameters; estimate a cooling capacity value for the cutter elements based on the design and one or more cooling parameters; and display one or more of the thermal impact values and the cooling capacity values responsive to a user input selecting one of a presentation on a per cutter element basis or as a function of a property of the cutter elements.

Yet other examples of the present disclosure are directed to a computing device including a memory configured to store a drill bit design. The drill bit design specifies parameters related to a plurality of cutter elements of the drill bit. The computing device also includes a processor coupled to the memory. The processor is configured to receive the drill bit design from the memory; estimate a thermal impact value for the cutter elements based on the design parameters and one or more drilling parameters; estimate a cooling capacity value for the cutter elements based on the design and one or more cooling parameters; and display, on a display device, one or more of the thermal impact values and the cooling capacity values responsive to a user input selecting one of a presentation on a per cutter element basis or as a function of a property of the cutter elements.

Still other examples of the present disclosure are directed to a drill bit designed according to the method above. Still other examples of the present disclosure are directed to a visual representation of data generated according to the method above.

### BRIEF DESCRIPTION OF THE DRAWINGS

For a detailed description of the preferred embodiments of the invention, reference will now be made to the accompanying drawings in which:

FIG. 1 is a schematic view of a drilling system including a drill bit in accordance with the principles described herein;

FIG. 2 is a perspective view of the dull bit of FIG. 1;

FIG. 3 is a flow chart of a method for performing thermal analysis of a drill bit and for determining cooling capacity of drilling fluid for cutting elements of the drill bit in accordance with various embodiments;

FIG. 4 is an example thermal distribution model of cutting elements of a drill bit in accordance with various embodiments;

FIG. 5 is a graph representing a delta-T thermal impact value on a per cutter element basis in accordance with various embodiments; and

FIG. 6 is a graphical representation of cooling capacity of drilling fluid and thermal impact values on a per cutter element basis, before and after changing one or more design parameters of a drill bit, in accordance with various embodiments.

### DETAILED DESCRIPTION

The following discussion is directed to various exemplary embodiments. However, one skilled in the art will understand that the examples disclosed herein have broad application, and that the discussion of any embodiment is meant only to be exemplary of that embodiment, and not intended to suggest that the scope of the disclosure, including the claims, is limited to that embodiment.

Certain terms are used throughout the following description and claims to refer to particular features or components. As one skilled in the art will appreciate, different persons may refer to the same feature or component by different names. This document does not intend to distinguish between components or features that differ in name but not function. The drawing figures are not necessarily to scale. Certain features and components herein may be shown exaggerated in scale or in somewhat schematic form and some details of conventional elements may not be shown in interest of clarity and conciseness.

In the following discussion and in the claims, the terms “including” and “comprising” are used in an open-ended fashion, and thus should be interpreted to mean “including, but not limited to . . . .” Also, the term “couple” or “couples” is intended to mean either an indirect or direct connection. Thus, if a first device couples to a second device, that connection may be through a direct connection, or through an indirect connection via other devices, components, and connections. In addition, as used herein, the terms “axial” and “axially” generally mean along or parallel to a central axis (e.g., central axis of a body or a port), while the terms “radial” and “radially” generally mean perpendicular to the central axis. For instance, an axial distance refers to a distance measured along or parallel to the central axis, and a radial distance means a distance measured perpendicular to the central axis. Any reference to up or down in the description and the claims will be made for purposes of clarity, with “up”, “upper”, “upwardly” or “upstream” meaning toward the surface of the borehole and with “down”, “lower”, “downwardly” or “downstream” meaning toward the terminal end of the borehole, regardless of the borehole orientation.

As previously described, PDC cutter elements are affected by thermal factors that lead to increased wear. In certain examples, the thermal factors acting on the various cutter elements is disproportionate, leading to increased wear on certain cutter elements relative to others. Although drilling fluid is used to cool the cutter elements, various drill bit designs may result in certain cutter elements having more or less available cooling capacity (e.g., exposure to drilling fluid) than others.

Embodiments described herein are directed to a method for determining a thermal impact value for the cutter elements of a drill bit, such as a temperature rise over a baseline temperature during operation of the drill bit, Additionally, a cooling capacity coefficient is determined for the cutter elements of the drill bit, and a visual representation of the thermal impact value and the cooling capacity of drilling fluid on a per cutter element basis is used to alter design parameters of the drill bit to reduce thermal wear on the cutter elements of the drill bit during operation. Embodiments described herein are also directed to drill bits designed using such methods. As will be described in more detail below, embodiments of the method and drill bits described herein seek to improve the thermal wear life of cutting elements of the drill bit.

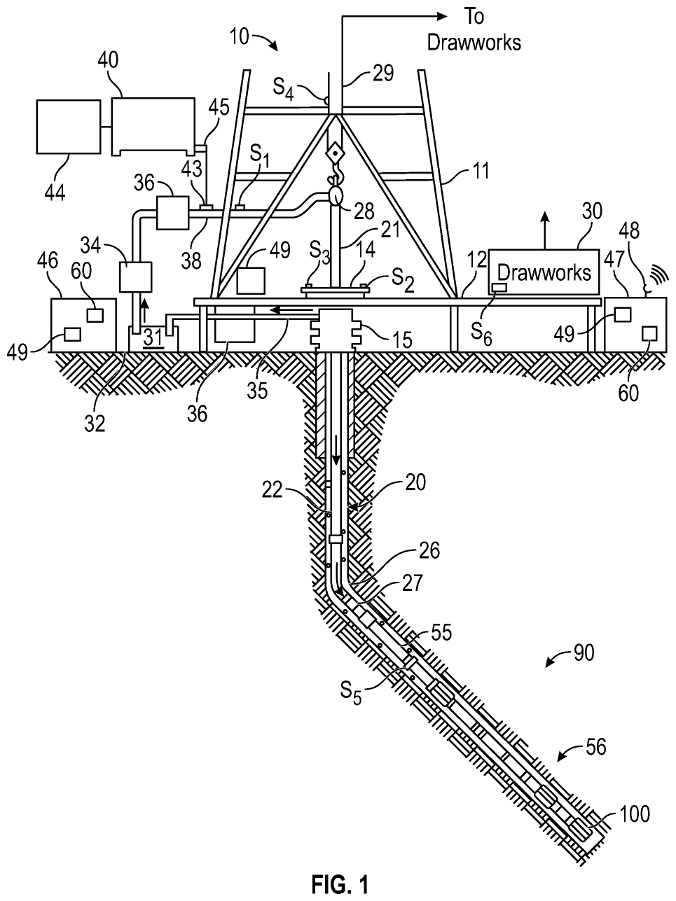

Referring now to FIG. 1, a schematic view of an embodiment of a drilling system 10 in accordance with the principles described herein is shown. Drilling system 10 includes a derrick 11 having a floor 12 supporting a rotary table 14 and a drilling assembly 90 for drilling a borehole 26 from derrick 11. Rotary table 14 is rotated by a prime mover such as an electric motor (not shown) at a desired rotational speed and controlled by a motor controller (not shown). In other embodiments, the rotary table (e.g., rotary table 14) may be augmented or replaced by a top drive suspended in the derrick (e.g., derrick 11) and connected to the drillstring (e.g., drillstring 20).

Drilling assembly 90 includes a drillstring 20 and a drill bit 100 coupled to the lower end of drillstring 20. Drillstring 20 is made of a plurality of pipe joints 22 connected end-to-end, and extends downward from the rotary table 14 through a pressure control device 15, such as a blowout preventer (BOP), into the borehole 26. The pressure control device 15 is commonly hydraulically powered and may contain sensors for detecting certain operating parameters and controlling the actuation of the pressure control device 15. Drill bit 100 is rotated with weight-on-bit (WOB) applied to drill the borehole 26 through the earthen formation. Drillstring 20 is coupled to a drawworks 30 via a kelly joint 21, swivel 28, and line 29 through a pulley. During drilling operations, drawworks 30 is operated to control the WOB, which impacts the rate-of-penetration of drill bit 100 through the formation. In this embodiment, drill bit 100 can be rotated from the surface by drillstring 20 via rotary table 14 and/or a top drive, rotated by downhole mud motor 55 disposed along drillstring 20 proximal bit 100, or combinations thereof (e.g., rotated by both rotary table 14 via drillstring 20 and mud motor 55, rotated by a top drive and the mud motor 55, etc.). For example, rotation via downhole motor 55 may be employed to supplement the rotational power of rotary table 14, if required, and/or to effect changes in the drilling process. In either case, the rate-of-penetration (ROP) of the drill bit 100 into the borehole 26 for a given formation and a drilling assembly largely depends upon the WOB and the rotational speed of bit 100.

During drilling operations a suitable drilling fluid 31 is pumped under pressure from a mud tank 32 through the drillstring 20 by a mud pump 34. Drilling fluid 31 passes from the mud pump 34 into the drillstring 20 via a desurger 36, fluid line 38, and the kelly joint 21. The drilling fluid 31 pumped down drillstring 20 flows through mud motor 55 and is discharged at the borehole bottom through nozzles in face of drill bit 100, circulates to the surface through an annular space 27 radially positioned between drillstring 20 and the sidewall of borehole 26, and then returns to mud tank 32 via a solids control system 36 and a return line 35. Solids control system 36 may include any suitable solids control equipment known in the art including, without limitation, shale shakers, centrifuges, and automated chemical additive systems. Control system 36 may include sensors and automated controls for monitoring and controlling, respectively, various operating parameters such as centrifuge rpm. It should be appreciated that much of the surface equipment for handling the drilling fluid is application specific and may vary on a case-by-case basis.

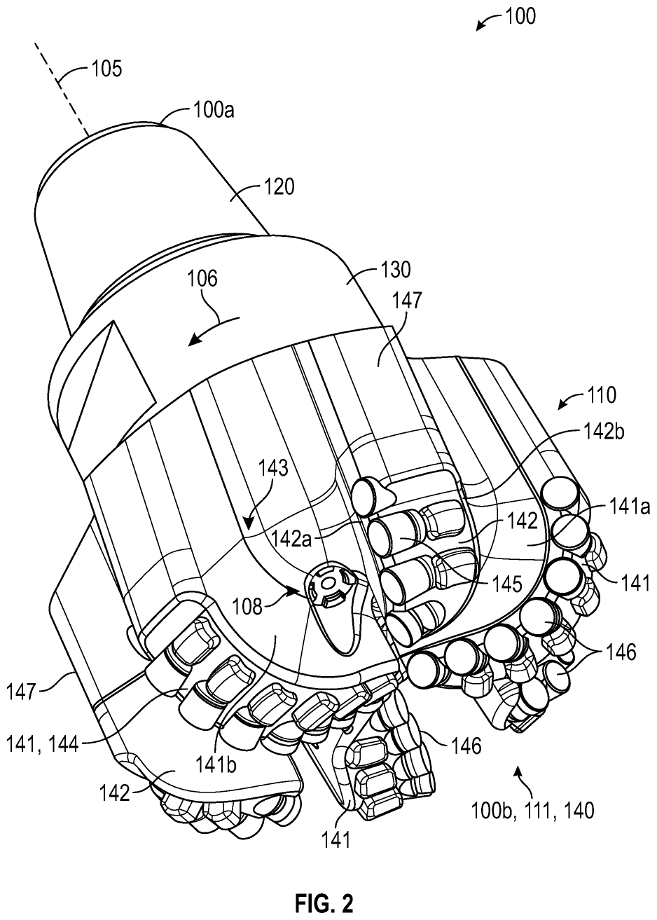

Referring now to FIG. 2, drill bit 100 is a fixed cutter bit, sometimes referred to as a drag bit, and is designed for drilling through formations of rock to form a borehole. Bit 100 has a central or longitudinal axis 105, a first or uphole end 100a, and a second or downhole end 100b. Bit 100 rotates about axis 105 in the cutting direction represented by arrow 106. In addition, bit 100 includes a bit body 110 extending axially from downhole end 100b, a threaded connection or pin 120 extending axially from uphole end 100a, and a shank 130 extending axially between pin 120 and body 110. Pin 120 couples bit 100 to drill string 20, which is employed to rotate the bit 100 to drill the borehole 26. Bit body 110, shank 130, and pin 120 are coaxially aligned with axis 105, and thus, each has a central axis coincident with axis 105.

The portion of bit body 110 that faces the formation at downhole end 100b includes a bit face 111 provided with a cutting structure 140. Cutting structure 140 includes a plurality of blades which extend from bit face 111. In some examples, cutting structure 140 includes three angularly spaced-apart primary blades 141, and three angularly spaced apart secondary blades 142. Although bit 100 is shown as having three primary blades 141 and three secondary blades 142, in general, bit 100 may comprise any suitable number of primary and secondary blades.

Primary blades 141 and secondary blades 142 are separated by drilling fluid flow courses 143. Each blade 141, 142 has a leading edge or side 141a, 142a, respectively, and a trailing edge or side 141b, 142b, respectively, relative to the direction of rotation 106 of bit 100.

Referring still to FIG. 2, each blade 141, 142 includes a cutter-supporting surface 144 for mounting a plurality of cutter elements 145. In particular, cutter elements 145 are arranged adjacent one another in a radially extending row proximal the leading edge of each primary blade 141 and each secondary blade 142. As used herein, the terms “leads,” “leading,” “trails,” and “trailing” are used to describe the relative positions of two structures (e.g., cutter element) on the same blade relative to the direction of bit rotation. In particular, a first structure that is disposed ahead or in front of a second structure on the same blade relative to the direction of bit rotation “leads” the second structure (i.e., the first structure is in a “leading” position), whereas the second structure that is disposed behind the first structure on the same blade relative to the direction of bit rotation “trails” the first structure (i.e., the second structure is in a “trailing” position).

Each cutter element 145 has a cutting face 146 and comprises an elongated and generally cylindrical support member or substrate which is received and secured in a pocket formed in the surface of the blade to which it is fixed. In general, each cutter element may have any suitable size and geometry. In this embodiment, each cutter element 145 has substantially the same size and geometry. Cutting face 146 of each cutter element 145 comprises a disk or tablet-shaped, hard cutting layer of polycrystalline diamond or other superabrasive material that is bonded to the exposed end of the support member. In the embodiments described herein, each cutter element 145 is mounted such that its cutting face 146 is generally forward-facing. As used herein, “forward-facing” is used to describe the orientation of a surface that is substantially perpendicular to, or at an acute angle relative to, the cutting direction of the bit (e.g., cutting direction 106 of bit 100). For instance, a forward-facing cutting face (e.g., cutting face 146) may be oriented perpendicular to the direction of rotation 106 of bit 100, may include a backrake angle, and/or may include a siderake angle. However, the cutting faces are preferably oriented perpendicular to the direction of rotation 106 of bit 100 plus or minus a 45° backrake angle and plus or minus a 45° siderake angle. In addition, each cutting face 146 includes a cutting edge adapted to positively engage, penetrate, and remove formation material with a shearing action, as opposed to the grinding action utilized by impregnated bits to remove formation material. Such cutting edge may be chamfered or beveled as desired. In this embodiment, cutting faces 146 are substantially planar, but may be convex or concave in other embodiments.

Referring still to FIG. 2, bit body 110 further includes gage pads 147 of substantially equal axial length measured generally parallel to bit axis 105. Gage pads 147 are circumferentially-spaced about the radially outer surface of bit body 110. Specifically, one gage pad 147 intersects and extends from each blade 141, 142. In this embodiment, gage pads 147 are integrally formed as part of the bit body 110. In general, gage pads 147 can help maintain the size of the borehole by a rubbing action when cutter elements 145 wear slightly under gage. Gage pads 147 also help stabilize bit 100 against vibration. Further, a nozzle 108 is seated in the lower end of each flow passage 107. Together, passages 107 and nozzles 108 distribute drilling fluid around cutting structure 140 to flush away formation cuttings and to remove heat from cutting structure 140, and more particularly cutting elements 145, during drilling.

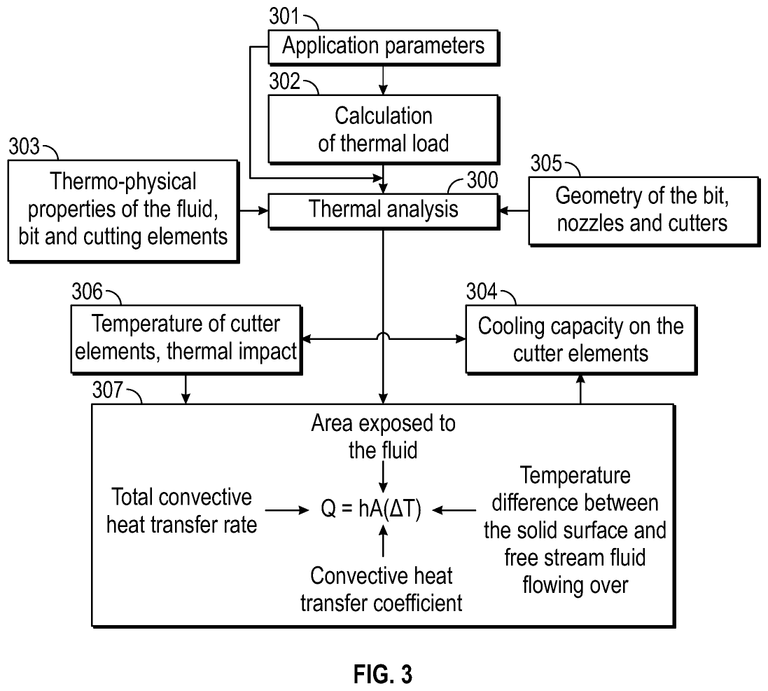

Referring now to FIG. 3, a flow chart of a method 300 for thermal analysis of the cutter elements 145 of the drill bit 100 is shown. The thermal analysis method 300 begins in block 302 with estimating a thermal bad value (e.g., thermal energy input) for the cutter elements 145 of the drill bit 100 using application parameters 301 (e.g., based on a received drill bit 100 design) such as rotary speed, depth of cut, cut areas, or other parameters relevant to engagement of the cutter element 145 with the earthen formation, as well as cutting forces (which are related to the type of material being cut through). Application parameters 301 may also include other information such as the flow rate or temperature of the drilling fluid pumped through the drill bit 100. The drill bit 100 design and other application parameters 301 may be stored in a memory of a computing device, which is accessible by software executed by the computing device to facilitate the performance of the method 300 described here and further below.

Next, using the parameters related to the geometry of the drill bit 100, the cutter elements 145, and the nozzles 108, for example from the drill bit 100 design (block 305), as well as thermophysical properties 303 of the drilling fluid, the drill bit 100, and the cutter elements 145, the thermal analysis 300 is conducted to calculate the temperature and the cooling capacities for each cutter element 145. The parameters related to the geometry of the drill bit 100 comprise relevant information about the geometry of the cutter element 145, its position and orientation on the drill bit 100, the relative distance between one cutter element 145 and other cutter elements 145 (e.g., adjacent cutter elements 145), and other geometrical features of the drill bit 100 or the nozzles 108, including their shape, location, size, and orientation (block 305). The thermophysical properties 303 for the thermal analysis 300 include thermal conductivity of various portions of the drill bit 100, such as the diamond table, substrate, and body, as well as viscosity, thermal conductivity, heat capacity, and density of the drilling fluid. The thermal analysis 300 may use inputs from application parameters 301 depending on the analysis technique.

Based on some or all of the foregoing parameters, a variety of methods can be employed to calculate cutter element 145 temperatures (block 306) or the cooling capacity of drilling fluid (block 304). For example, finite element analysis, finite volume analysis, or similar numerical techniques can be used to solve the governing fluid and energy equations in the region (e.g., of the bit 100) of interest. A direct output of such a solution may be temperature of various cutter elements 145 and the drilling fluid in proximity to those cutter elements 145. The cooling capacity of the drilling fluid may be computed based on the temperature outputs and other physical properties of the drilling fluid and the cutter elements 145. For example, different analysis techniques may be used to obtain these outputs with different degrees of accuracy, and there is no required method to obtain such outputs. Other possible techniques can include analytical solutions and empirical equations, among others.

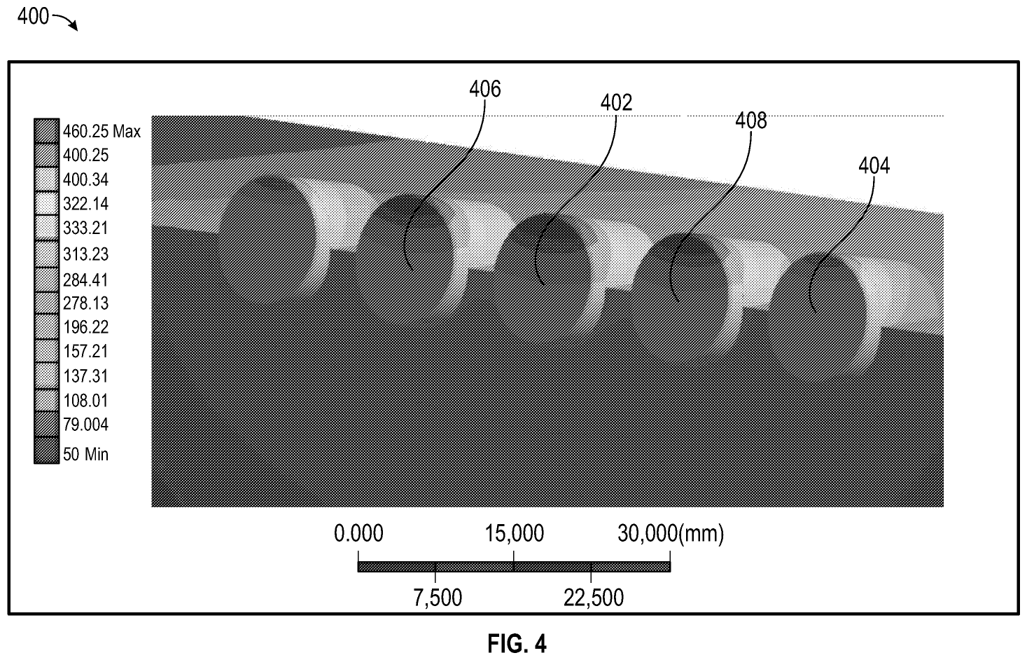

Referring briefly to FIG. 4, a thermal distribution model 400 is shown for five cutter elements 145 as a visual example of the thermal impact value for an example grouping of cutter elements 145. As can be seen, the thermal distribution model 400 includes a middle cutter element 402 and an outer cutter element 404. The middle cutter element 402 has an increased thermal impact value relative to the outer cutter element 404. Certain factors that lead to the increased thermal impact value of the middle cutter element 402 may include its proximity to other cutter elements (e.g., having cutter elements 406, 408 in close proximity, whereas the cutter element 404 only has cutter element 408 in close proximity), and the thermal conductivity of the surrounding material (e.g., the material near the middle cutter element 402 is warmer than the material near the outer cutter element 404, and thus more heat is conducted away from the outer cutter element 404 than the middle cutter element 402). Additionally, the available amount of cooling capacity provided by drilling fluid can also affect these temperatures. Therefore, it is also possible that the outer cutter element 404 is provided with relatively higher cooling capacity from the drilling fluid, contributing to its lower temperature.

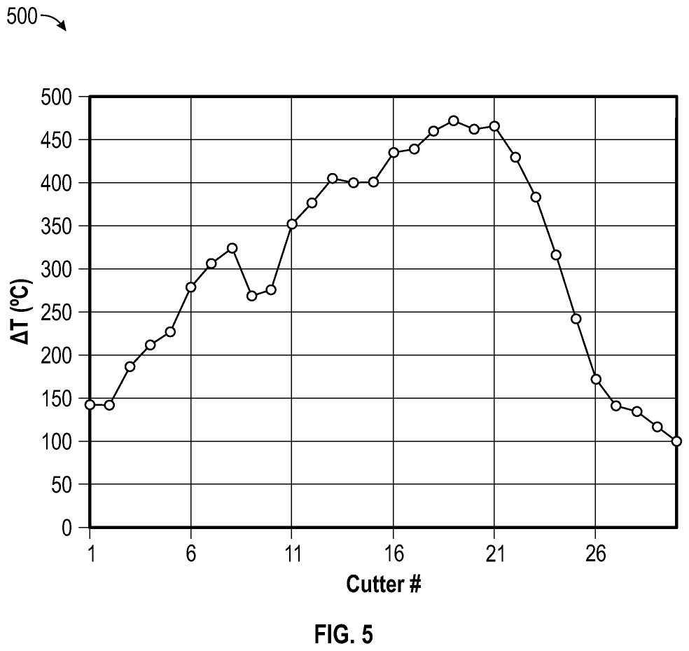

Referring now to FIG. 5, an example graph 500 of thermal impact values on a per cutter element 145 basis is shown. In the example graph 500, the thermal impact values are delta-T values, or a temperature rise for each cutting element 145 relative to a baseline value. In an example, the baseline value is the temperature of drilling fluid being pumped through the drill bit 100. As can be seen in the example graph 500, certain cutter elements 145 experience a larger delta-T relative to the drilling fluid temperature than other cutter elements. Thus, it is important to not only consider the temperature rise of specific cutter elements 145, but also the cooling capacity available to those cutter elements 145 by virtue of the drill bit 100 design and the drilling fluid properties. Although not shown in FIG. 5, other embodiments of the present disclosure may present thermal impact values (and/or cooling capacities) as a function of cutter element 145 radius, or other physical properties of cutter elements 145 that, for example, differ among at least some of the cutter elements 145. The determination of how to present the thermal impact values (and/or cooling capacities) may be responsive to a user input or selection.

Referring back to FIG. 3, the temperature output 306 of thermal analysis 300 may correspond to any location on a cutter element 145. In some examples, the cutter tip may be a more relevant location as it typically has the highest temperature due to engaging the earthen formation. However, in other examples, the temperature at other locations of the cutter element 145 is determined and used to evaluate a thermal impact factor.

Still referring to FIG. 3, in view of the equation 307, the method 300 for thermal analysis of the cutter elements 145 of the drill bit 100 also includes, in block 304, calculating or estimating a convective heat transfer rate for the cutter elements 145, In some cases, the cooling capacity of drilling fluid is then represented by either the convective cooling coefficient, h, which depends on a variety of factors including physical properties of the fluid and temperature of the cutter surface in contact with fluid, fluid velocity, local turbulence, viscosity, etc. In some cases, the cooling capacity comprises an area integral of the cooling coefficient h, over a certain surface area of the cutter element 145, which can be represented as h*A in equation 307. In another case, the total convective heat transfer rate, Q, can be the cooling capacity of the drilling fluid. The cooling capacity of the drilling fluid may be calculated for the front face of the cutter element 145 where the cutter element 145 is exposed to the drilling fluid. However, other cutter faces, or combinations thereof, may also be used to evaluate the cooling capacity.

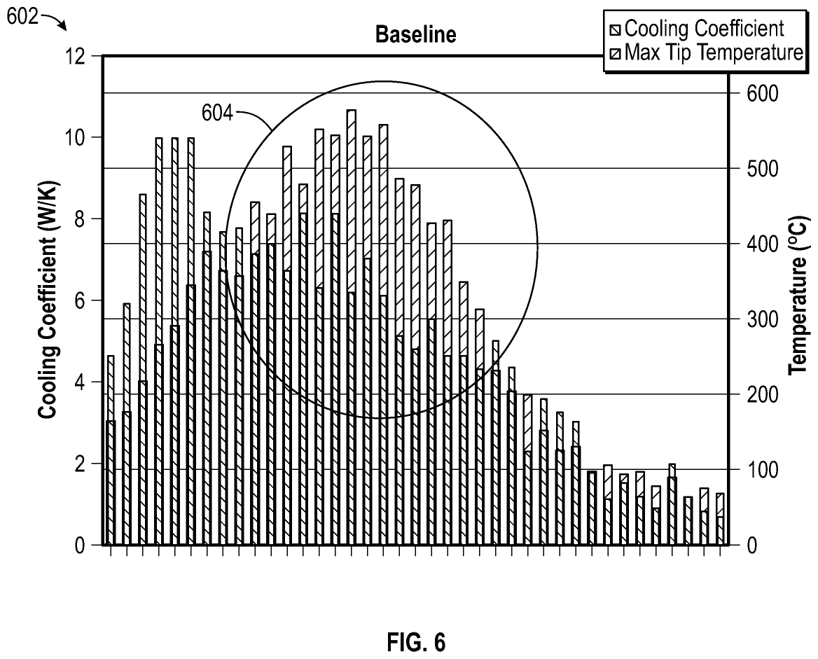

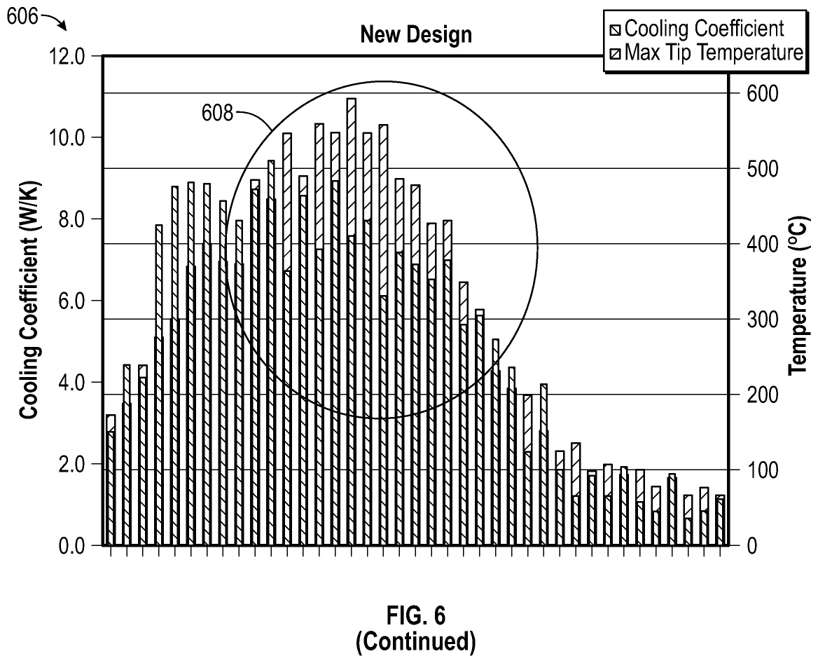

Once the cooling capacity of the drilling fluid and thermal impact values have been calculated for the cutter elements 145 of the drill bit 100, embodiments of the present disclosure may include generating a graphical display of the cooling capacities and the thermal impact values on a per cutter element 145 basis. Turning to FIG. 6, an example of such a graphical display is shown. In FIG. 6, a preliminary graphical display 602 represents the cooling capacities of drilling fluid and the thermal impact values for a number of cutter elements 145. The cooling coefficients are expressed in Watts, Watts/Kelvin or Watts/Kelvin/area depending on the chosen unit determined in FIG. 3. The thermal impact values are represented as delta-T above a baseline (e.g., drilling fluid temperature) in degrees Celsius. The highlighted area 604 demonstrates certain of the cutter elements 145 for which the thermal impact value is highest, but where cooling capacities are relatively lower. This indicates a potential imbalance between thermal energy generation and removal. Those cutter elements 145 in the area 604 may experience premature thermal wear relative to the cutter elements 145 outside of the area 604, where adequate cooling capacity versus thermal impact exists.

In certain embodiments of the present disclosure, remedial action may be taken to address the imbalance between the cooling coefficients and the thermal impact values in the highlighted area 604. The remedial action may include changing design parameters of the drill bit 100 such as position, shape, or other physical attributes of the cutter elements 145; and position, shape, or other physical attributes of the nozzles 108. In some examples, remedial action is only taken if the thermal impact for at least one cutter element 145 outweighs the cooling capacity for that cutter element 145 compared to other cutter elements. Although cooling capacity and thermal impact values are not of the same units, in some embodiments a correlation between the two units is established, and a comparison between values takes place, where a thermal impact value exceeding a corresponding cooling capacity by at least a threshold amount is considered (i.e., remedial action may not be needed if the cooling capacity for the cutter element 145 is sufficiently close in value to the thermal impact value for that cutter element 145). In certain embodiments, the remedial action taken may be manual (e.g., an engineer modifies design parameters of the drill bit 100), while in other embodiments, the remedial action taken may be automated (e.g., a computer program modifies design parameters of the drill bit 100 based on an understanding of the impact(s) of such modifications on thermal wear life of the cutter elements 145 of the drill bit 100).

FIG. 6 also shows a subsequent graphical display 606, which represents the cooling capacities and the thermal impact values for the cutter elements 145 of a drill bit 100 following the changes to design parameters of the drill bit 100. In particular, the subsequent graphical display 606 includes a highlighted area 608 that corresponds to the highlighted area 604 of the preliminary graphical display 602. As can be seen, after the changes to design parameters of the drill bit 100, the cooling capacities in the highlighted area 608 have been improved upon, and thus a relative improvement value is demonstrated in the subsequent graphical display 606. Additionally, although certain other cooling capacities outside of the highlighted area 608 have been reduced, these reduced cooling capacities are still within a tolerable range of the corresponding low thermal impact values in those areas outside the area 608 (e.g., within a threshold amount of the corresponding thermal impact value). In other examples, where thermal impact values have not changed during an update to drill bit design parameters, but the cooling capacities have changed, the change in cooling capacities is demonstrated by displaying or presenting cooling capacities from before and after the updates to design parameters to demonstrate the improvements.

By modifying the design parameters of the drill bit 100 in response to the preliminary graphical display 602, the thermal wear on cutter elements 145 of the drill bit 100 is improved upon, which in turn increases the expected lifespan of the drill bit 100. In some embodiments, the design parameters of the drill bit 100 are manually adjusted (e.g., by an engineer viewing the preliminary graphical display 602). In other embodiments, the design parameters of the drill bit 100 are automatically adjusted, for example by a software tool. In certain cases, the software tool modifies certain design parameters of the drill bit 100 and again performs the methods described herein to generate one or more intermediate plots of cooling capacities and thermal impact values that represent the impact of the modifications to the drill bit 100 design parameters. In this way, the software tool may take an iterative approach to modifying design parameters of the drill bit 100 to improve the overall thermal wear characteristics (e.g., improve or reduce the imbalance between the cooling capacities and thermal impact values for the cutter elements 145) for the drill bit 100.

Embodiments of this disclosure may include a computing device and/or associated software, embodied on a non-transitory computer-readable medium that, when executed by the computing device (e.g., a processor), causes the computer to perform some or all of the method steps described herein. Further, the various described graphical displays may be displayed on a computer monitor, printed as a hard copy, or otherwise displayed to a user. In the examples where modifications to the design parameters of a drill bit 100 are carried out by a software tool executed on a computer, one or more of the described graphical display elements may not be actually displayed to a user, although the data that would otherwise be displayed (e.g., the cooling capacities and thermal impact values on a per cutter element 145 basis) may be taken into account by the software tool in modifying the design parameters of the drill bit 100.

While preferred embodiments have been shown and described, modifications thereof can be made by one skilled in the art without departing from the scope or teachings herein. The embodiments described herein are exemplary only and are not limiting. Many variations and modifications of the systems, apparatus, and processes described herein are possible and are within the scope of the disclosure. For example, the relative dimensions of various parts, the materials from which the various parts are made, and other parameters can be varied. Similarly, methods to calculate the thermal impact or cooling capacity may also vary which may include, individually or collectively, different numerical algorithms, empirical correlations, analytical solutions or approximations. Accordingly, the scope of protection is not limited to the embodiments described herein, but is only limited by the claims that follow, the scope of which shall include all equivalents of the subject matter of the claims. Unless expressly stated otherwise, the steps in a method claim may be performed in any order. The recitation of identifiers such as (a), (b), (c) or (1), (2), (3) before steps in a method claim are not intended to and do not specify a particular order to the steps, but rather are used to simplify subsequent reference to such steps.

What is claimed is:

1. A method, comprising:
receiving a drill bit design, the design specifying design parameters related to a plurality of cutter elements of the drill bit;
estimating a thermal impact value for the cutter elements based on the design parameters and one or more drilling parameters;
estimating a cooling capacity value for the cutter elements based on the design and one or more cooling parameters; and
presenting one or more of the thermal impact values and the cooling capacity values responsive to a user input selecting one of a presentation on a per cutter element basis or as a function of a property of the cutter elements.

2. The method of claim 1, further comprising identifying a cutter element for which the thermal impact value differs from the cooling capacity value by more than a threshold amount.

3. The method of claim 2, further comprising updating one or more design parameters of the drill bit to reduce the imbalance between the thermal impact value and the cooling capacity for the identified cutter element, wherein the updates to the design parameters decrease the thermal impact value for the identified cutter element, increase the cooling capacity for the identified cutter element, or both decrease the thermal impact value and increase the cooling capacity for the identified cutter element.

4. The method of claim 3, further comprising presenting a relative improvement value of thermal impact or cooling capacities responsive to a user input selecting one of presentation on a per cutter element basis or as a function of a property of the cutter elements.

5. The method of claim 3, further comprising manufacturing a drill bit using the updated design parameter.

6. The method of claim 1, wherein the design parameter comprises one or more selected from the list consisting of: location and orientation of cutter elements on the drill bit; number of cutter elements; type, size, shape, and length of cutter elements; drilling fluid flow rate; number of drilling fluid nozzles on the drill bit; size, shape, location, and orientation of nozzles; geometry of the drill bit; and drilling fluid type and flow rate.

7. The method of claim 1, wherein estimating the thermal impact value further comprises estimating the thermal impact value based on one or more selected from the list consisting of: rotary speed, depth of cut, cut areas, or other parameters relevant to engagement of the cutter element with the earthen formation; type of the earthen formation; cutting forces; location and orientation of cutter elements on the drill bit; number of cutter elements; type, size, shape, and length of cutter elements; number of drilling fluid nozzles on the drill bit; size, shape, location, and orientation of nozzles; geometry of the drill bit; and drilling fluid type and flow rate.

8. A non-transitory, computer-readable medium containing instructions that, when executed by a processor, cause the processor to:
receive a drill bit design from a memory, the design specifying design parameters related to a plurality of cutter elements of the drill bit;
estimate a thermal impact value for the cutter elements based on the design parameters and one or more drilling parameters;
estimate a cooling capacity value for the cutter elements based on the design and one or more cooling parameters; and
display one or more of the thermal impact values and the cooling capacity values responsive to a user input selecting one of a presentation on a per cutter element basis or as a function of a property of the cutter elements.

9. The non-transitory, computer-readable medium of claim 8, wherein the instructions, when executed, further cause the processor to identify a cutter element for which the thermal impact value differs from the cooling capacity value by more than a threshold amount.

10. The non-transitory, computer-readable medium of claim 9, wherein the instructions, when executed, further cause the processor to update one or more design parameters of the drill bit to reduce the imbalance between the thermal impact value and the cooling capacity for the identified cutter element, wherein the updates to the design parameters decrease the thermal impact value for the identified cutter element, increase the cooling capacity for the identified cutter element, or both decrease the thermal impact value and increase the cooling capacity for the identified cutter element.

11. The non-transitory, computer-readable medium of claim 10, wherein the instructions, when executed, further cause the processor to display a relative improvement value of thermal impact or cooling capacities responsive to a user input selecting one of presentation on a per cutter element basis or as a function of a property of the cutter elements.

12. The non-transitory, computer-readable medium of claim 8, wherein the design parameter comprises one or more selected from the list consisting of: location and orientation of cutter elements on the drill bit; number of cutter elements; type, size, shape, and length of cutter elements; drilling fluid flow rate; number of drilling fluid nozzles on the drill bit; size, shape, location, and orientation of nozzles; geometry of the drill bit; and drilling fluid type and flow rate.

13. The non-transitory, computer-readable medium of claim 8, wherein estimating the thermal impact value further comprises estimating the thermal impact value based on one or more selected from the list consisting of: rotary speed, depth of cut, cut areas, or other parameters relevant to engagement of the cutter element with the earthen formation; type of the earthen formation; cutting forces; location and orientation of cutter elements on the drill bit; number of cutter elements; type, size, shape, and length of cutter elements; number of drilling fluid nozzles on the drill bit; size, shape, location, and orientation of nozzles; geometry of the drill bit; and drilling fluid type and flow rate.

14. A computing device, comprising:
a memory configured to store a drill bit design, the design specifying design parameters related to a plurality of cutter elements of the drill bit; and
a processor coupled to the memory, the processor configured to:
receive the drill bit design from the memory,
estimate a thermal impact value for the cutter elements based on the design parameters and one or more drilling parameters;
estimate a cooling capacity value for the cutter elements based on the design and one or more cooling parameters; and
display, on a display device, one or more of the thermal impact values and the cooling capacity values responsive to a user input selecting one of a presentation on a per cutter element basis or as a function of a property of the cutter elements.

15. The computing device of claim 14, wherein the processor is further configured to identify a cutter element for which the thermal impact value differs from the cooling capacity value by more than a threshold amount.

16. The computing device of claim 15, wherein the processor is further configured to update one or more design parameters of the drill bit to reduce the imbalance between the thermal impact value and the cooling capacity for the identified cutter element, wherein the updates to the design parameters decrease the thermal impact value for the identified cutter element, increase the cooling capacity for the identified cutter element, or both decrease the thermal impact value and increase the cooling capacity for the identified cutter element.

17. The computing device of claim 16, wherein the processor is further configured to display a relative improvement value of thermal impact or cooling capacities responsive to a user input selecting one of presentation on a per cutter element basis or as a function of a property of the cutter elements.

18. The computing device of claim 14, wherein the design parameter comprises one or more selected from the list consisting of: location and orientation of cutter elements on the drill bit; number of cutter elements; type, size, shape, and length of cutter elements; drilling fluid flow rate; number of drilling fluid nozzles on the drill bit; size, shape, location, and orientation of nozzles; geometry of the drill bit; and drilling fluid type and flow rate.

19. The computing device of claim 14, wherein estimating the thermal impact value further comprises estimating the thermal impact value based on one or more selected from the list consisting of: rotary speed, depth of cut, cut areas, or other parameters relevant to engagement of the cutter element with the earthen formation; type of the earthen formation; cutting forces; location and orientation of cutter elements on the drill bit; number of cutter elements; type, size, shape, and length of cutter elements; number of drilling fluid nozzles on the drill bit; size, shape, location, and orientation of nozzles; geometry of the drill bit; and drilling fluid type and flow rate.
